(19) United States
(12) Patent Application Publication
(10) Pub. No.: US 2020/0367357 A1
(43) Pub. Date: Nov. 19, 2020

(54) FLAT-WIRE COPPER VERTICAL LAUNCH MICROWAVE INTERCONNECTION METHOD

(71) Applicant: RAYTHEON COMPANY, Waltham, MA (US)

(72) Inventors: James E. Benedict, Lowell, MA (US); Paul A. Danello, Marlborough, MA (US); Mary K. Herndon, Littleton, MA (US); Thomas V. Sikina, Acton, MA (US); Andrew R. Southworth, Lowell, MA (US); Kevin Wilder, Derry, NH (US)

(21) Appl. No.: 15/930,888

(22) Filed: May 13, 2020

(30) Foreign Application Priority Data
May 14, 2019 (US) PCT/US2019/032129

(51) Int. Cl. H05K 1/02; H05K 1/11; H05K 3/46; H05K 3/40

(52) U.S. Cl. CPC H05K 1/0243; H05K 3/4046; H05K 3/4647; H05K 1/116

(57) ABSTRACT

A circuit structure includes a signal substrate having a signal trace formed thereon and a microstrip substrate disposed above the signal substrate that includes a microstrip trace formed thereon and a hole passing through it. The circuit structure also includes a conductor passing through and substantially filling the hole passing through the microstrip substrate and electrically contacting the signal trace on the signal substrate and a flat wire connector electrically connecting the microstrip trace to a first end of the conductor, the flat wire connector being arranged such that a gap is formed between the flat wire connector and a top surface of the microstrip substrate.

### CROSS-REFERENCE TO RELATED APPLICATION

This application claims priority under 35 U.S.C. § 119(e) to International Patent Application Serial No. PCT/US2019/032129, titled “FLAT-WIRE COPPER VERTICAL LAUNCH MICROWAVE INTERCONNECTION METHOD,” filed on May 14, 2019, which is hereby incorporated by reference in its entirety.

### BACKGROUND

The present disclosure relates to a radio frequency printed circuit board circuits and, in particular, to utilizing flat wire copper vertical launch methods to form a multilayer circuit structure that can be used in radiofrequency circuits.

In an effort the produce more compact, radio frequency (RF) and electromagnetic circuits may be manufactured using conventional printed circuit board (PCB) processes. Some RF and electromagnetic circuits may include several layers and, thus, require electrical connections between conductors disposed on different layers. The term commonly used to describe such an interlayer-connection is a “via.”

Conventional PCB manufacturing processes may form a via to provide electrical conducting between layers. These process can include multiple differing steps, including baths in hazardous materials, and may require multiple iterations, extensive labor, etc., all leading to higher cost and slower turnaround time.

Further, the conventional manner in which vias can be formed is limited by size. That is, conventional methods are not adept at forming small features. This lower size limit can limit the range of highest frequency signals that may be supported by such devices.

### SUMMARY

According to one embodiment, a circuit structure that includes a signal substrate having a signal trace formed thereon and a microstrip substrate disposed above the signal substrate that includes a microstrip trace formed thereon and a hole passing through it is disclosed. The circuit also includes a conductor passing through and substantially filling the hole passing through the microstrip substrate and electrically contacting the signal trace on the signal substrate and a flat wire connector electrically connecting the microstrip trace to a first end of the conductor, the flat wire connector being arranged such that a gap is formed between the flat wire connector and a top surface of the microstrip substrate.

According to any prior embodiment of a circuit structure, the flat wire connector is soldered to the microstrip trace and a top of the conductor.

According to any prior embodiment of a circuit structure, the conductor is a solid wire.

According to any prior embodiment of a circuit structure, a second end of the conductor is soldered to signal trace.

According to any prior embodiment of a circuit structure, a top of the conductor extend above the top surface of the microstrip substrate.

According to any prior embodiment of a circuit structure, the circuit, further includes an intermediate substrate located between the signal substrate and the microstrip substrate that includes a hole formed therein and that aligns with the hole passing through the microstrip substrate.

According to any prior embodiment of a circuit structure, the conductor passes thought both the hole passing through the microstrip substrate and the hole formed in the intermediate substrate.

Also disclosed is a method of manufacturing a circuit structure, the method comprising: forming a signal trace on a signal substrate; bonding a microstrip substrate directly or indirectly above the signal substrate; forming a hole in microstrip substrate; passing a conductor through the hole to substantially fill the hole passing through the microstrip substrate such that it electrically contacts the signal trace on the signal substrate; and electrically connecting a flat wire connector to the microstrip and to a first end of the conductor such that a gap is formed between the flat wire connector and a top surface of the microstrip substrate.

According to any prior method, the method can further include forming a solder ball on the signal trace before passing the conductor through the hole.

According to any prior method, the method can further include applying heat to the conductor to reflow the solder ball.

According to any prior method, the method can further include forming a solder ball on a second end of the conductor before passing it through the hole; and applying heat to the conductor to reflow the solder ball after the conductor is passed through the hole.

According to any prior method, electrically connecting the flat wire connector to the microstrip and to the first end of the conductor includes soldering the flat wire connector to the microstrip and soldering the flat wire connector to the first end of the conductor.

According to any prior method, the conductor is a solid wire.

According to any prior method, the method can further include: before bonding the microstrip substrate over the signal substrate, bonding an intermediate substrate the signal substrate; and forming a hole through the intermediate substrate.

According to any prior method, passing a conductor through the hole in the microstrip substrate includes passing the conductor through the hole formed in the intermediate substrate.

In one embodiment, a coplanar waveguide circuit structure is disclosed. The coplanar waveguide circuit structure includes a substrate that includes a first and second microstrip ground traces formed on a top surface thereof, the substrate also including a signal microstrip formed on the top surface and between the first and second microstrip ground traces and a ground plane dispose on a bottom surface of the substrate. The coplanar waveguide circuit structure also includes a first conductor passing through and substantially filling a first hole passing through the substrate and electrically contacting the ground plane and a first flat wire connector electrically connecting the first microstrip ground trace to a first end of the first conductor. The first flat wire connector being arranged such that a first gap is formed between the first flat wire connector and the top surface of the substrate.

The coplanar waveguide circuit structure can also include: a second conductor passing through and substantially filling a second hole passing through the substrate and electrically contacting the ground plane; and a second flat wire connector electrically connecting the second microstrip ground trace to a first end of the second conductor, the second flat wire connector being arranged such that a second gap is formed between the second flat wire connector and the top surface of the substrate.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts:

FIG. 1 shows a circuit structure according to one embodiment;

FIGS. 2A-2E shows various process steps that can be used to form the circuit structure of FIG. 1;

FIG. 3 shows a detailed depiction of how the flat wire connector connects the microstrip to the conductor of FIG. 1 according to one embodiment; and

FIG. 4 shows an example of a co-planar wave guide that includes two vertical launch structures.

### DETAILED DESCRIPTION

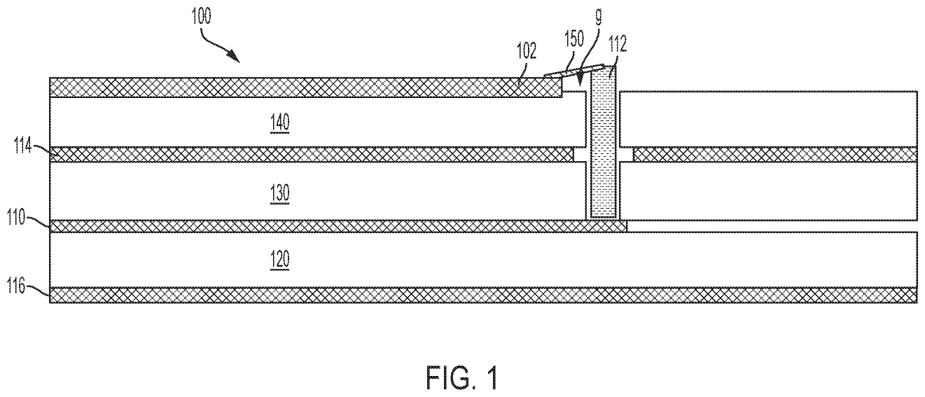

FIG. 1 is a cross-section view of a schematic illustrating an electromagnetic circuit structure 100 formed according to one embodiment. The circuit can be, for example, an RF frequency transmitter or receiver. In one embodiment, the circuit 100 can be formed by a process disclosed later herein. Such manufacturing processes described herein may be particularly suitable for fabrication of such circuit structures having small circuit features capable of supporting electromagnetic signals in the range of 8 to 75 GHz or more, for example, and up to 300 GHz or more, using suitable subtractive (e.g., milling, drilling) and additive (e.g., 3-D printing, filling) manufacturing equipment. Electromagnetic circuit in accord with systems and methods described herein may be particularly suitable for application in 28 to 70 GHz systems, including millimeter wave communications, sensing, ranging, etc. Aspects and embodiments described may also be suitable for lower frequency applications, such as in the S-band (2-4 GHz), X-band (8-12 GHz), or others.

Electromagnetic circuits and methods of manufacture in accord with those described herein include various additive and subtractive manufacturing techniques to produce electromagnetic circuits and components capable of handling higher frequencies, with lower profiles, and at reduced costs, cycle times, and design risks, than conventional circuits and methods. Examples of techniques include machining (e.g., milling) of conductive material from a surface of a substrate to form signal traces (e.g., signal conductors, striplines) or apertures, which may be of significantly smaller dimensions than allowed by conventional PCB processes, machining of one or more substrates to form a trench, using 3-dimensional printing techniques to deposit printed conductive inks into the trench to form a continuous electric barrier (e.g., a Faraday wall) (e.g., as opposed to a series of ground vias that require minimum spacing), “vertical launch” signal paths formed by machining (such as milling, drilling, or punching) a hole through a portion of substrate and in which a wire is placed (and/or conductive ink is printed) to make electrical contact to a signal trace disposed on a surface of the substrate (or an opposing substrate), and using 3-dimensional printing techniques to deposit printed resistive inks to form resistive components.

Any of the above example techniques and/or others (e.g., soldering and/or solder reflow), may be combined to make various electromagnetic components and/or circuits. Aspects and examples of such techniques are described and illustrated herein with respect to a radio frequency interconnect to contain and convey an electromagnetic signal along a layer of an electromagnetic circuit in one dimension and vertically through to other layers of the circuit in another dimension. The techniques described herein may be used to form various electromagnetic components, connectors, circuits, assemblies, and systems.

With reference back to FIG. 1, the circuit 100 includes a microstrip trace 102 such as a transmission line or antenna structure. The microstrip trace 102 is electrically connected to an internal signal trace (or stripline trace) 110 such as a feed or signal line by a conductor 112. The conductor 112 can be referred to a vertical launch structure herein.

One or more substrate layers are disposed between the microstrip trace 102 and the internal signal trace 110. As shown, two substrate layers 130, 140 are formed between the microstrip trace 102 and the internal signal trace 110. This is not meant as limiting but, rather is provide as an example. The number of substrate layers can be as few as one or may be greater than two, for example, 3, 4, . . . 100.

The microstrip trace 102 can be fed by the conductor 112 with a signal provided by the internal signal trace 110. The microstrip trace 102 may, alternatively, receive a signal from another source and provide that signal to the internal signal trace 110 via the conductor 112. In one embodiment, the conductor 112 may convey one or more signals in both directions at the same time (e.g., bidirectional) between the microstrip trace 102 and the internal signal trace 110.

In some other instances of a circuit that includes a conductor 112, the microstrip trace 102 is connected directly on top of the conductor 112. However, as the conductor can have a different coefficient of thermal expansion than the substrates (e.g., substrates 120, 130, 140), such a configuration can lead the microstrip trace 102 disconnecting from the conductor. In embodiments herein, the concept of a flat wire vertical launch is introduced. In such embodiment, the connection between the microstrip trace 102 and the conductor 112 is made by flat wire connector 150 that is displaced from and, for at least a portion of its length, does not contact a substrate on which the microstrip trace 102 is formed or otherwise located. As shown in FIG. 1, a gap g exists between the flat wire connector 150 and the upper surface of the substrate 140. In this case, the substrate 140 can be referred to as a “top” or “microstrip” substrate. In cases where the connector and the substrates are exposed to heat and expand at different rates, connecting the microstrip trace 102 to the conductor 112 by made by flat wire connector 150 will allow for relative movement without breaking the electrical connection between the conductor 112 and the microstrip trace 102. Stated differently, by providing the flat wire connector 150, strain relief for long vertical launch interconnections is achieved. This can allow, for example, for vertical launch connections (e.g., a distance between the tops of substrates 120 and 140) over 0.090 in.

In various embodiments, the conductor 112 is inserted into an opening in one or more substrates and/or layers of the circuit 100, and may be physically and electrically secured to the microstrip trace 102 by a solder joint, such as by application of a solder bump on the internal signal trace 110 at one or more locations or surfaces followed by a solder reflow operation at some point during the manufacturing process. Accordingly, the conductor 112 is not required to be compression or force fit inside the opening (hole), and may have a loose fit relative to the wall(s) of the opening.

Openings in the substrates 120, 130, 140 to accommodate the conductor 112 may be formed by milling or drilling a hole appropriately sized to accommodate the conductor 112. The conductor 112 may be a wire, such as a copper or other conductive wire, which may be solid, hollow, single-stranded, or multi-stranded. In various embodiments, the milled hole(s) and/or the diameter of the conductor 112 may be as small as about 5 mils (0.005 inches) in diameter, or even as small as about 2 or 3 mils with suitable machining equipment.

In FIG. 1 the circuit include other optional elements such as a ground plane 114 between the top or microstrip substrate 140 and the illustrated middle or intermediate substrate 130. The example shown in FIG. 1 further includes a second ground plane 116 formed on an opposing face of the bottom or signal carrying substrate 120, such that the internal signal trace 110 is provided with a pair of ground planes 114, 116. The ground planes 160, 170 may be formed by an electroplated material, such as copper, disposed on one or more surfaces of a respective substrate.

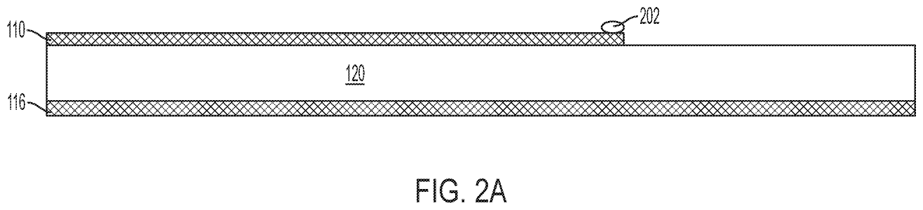

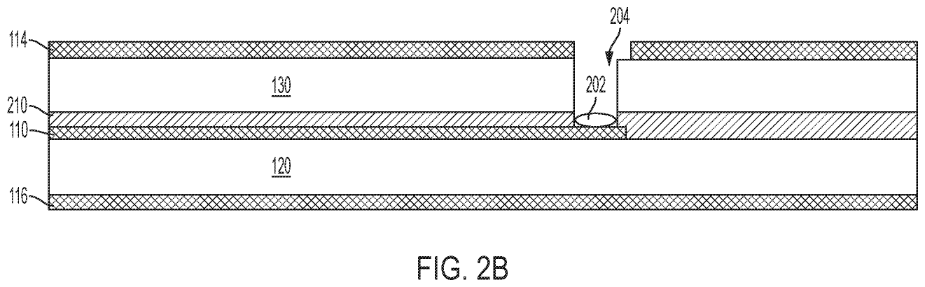

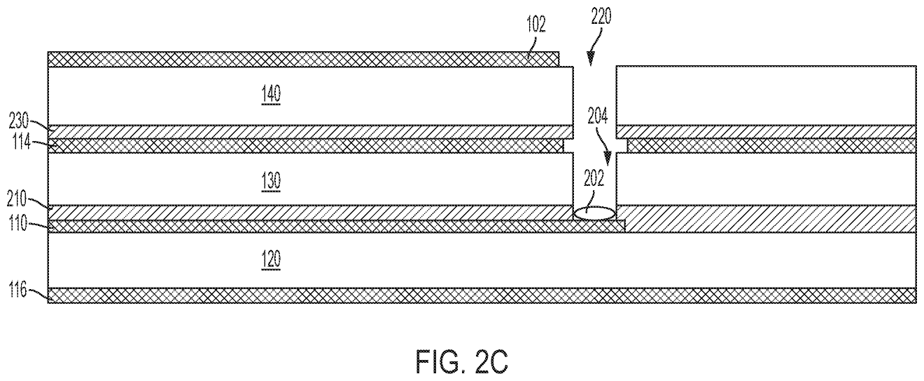

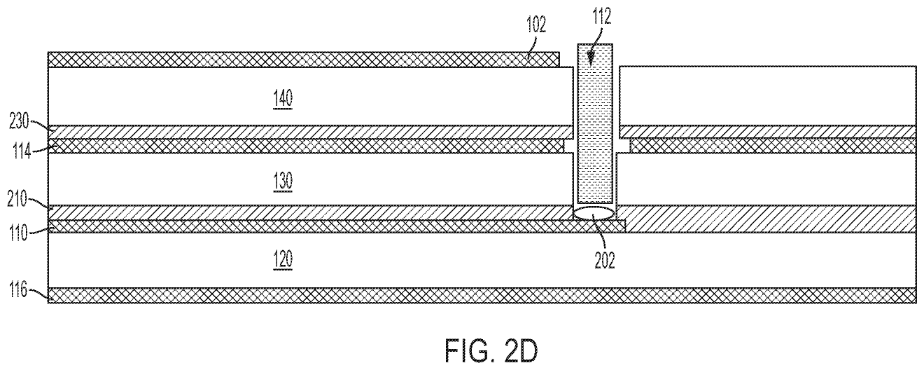

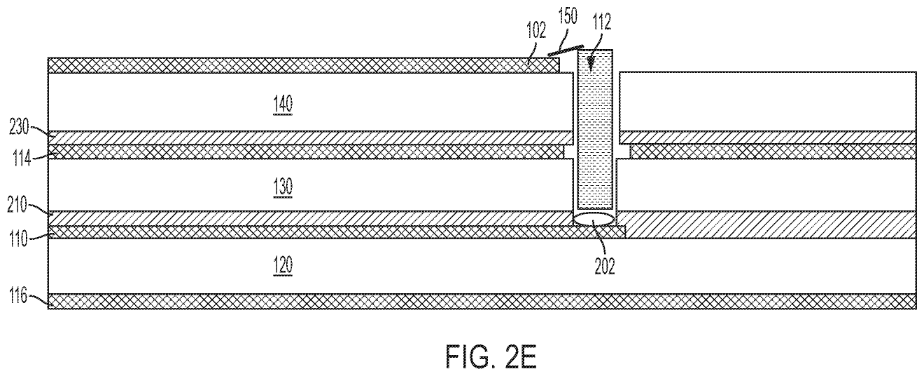

FIGS. 2A-2E show a build-up process of forming a circuit such as the circuit shown in FIG. 1 that includes a flat wire vertical launch. Initially, a bottom or signal carrying substrate 120 is provided. Electrical conducting material is deposited on a top (internal signal trace 110) and can optionally also be provided on the bottom (second ground plane 116) of the signal carrying substrate 120. The internal signal trace 110 may be formed from at least one of the faces of conducting material by milling away excess conductive material to form the internal signal trace 110.

The internal signal trace 110 (as well as the microstrip 102 of FIG. 1) or any other electrical connection formed or otherwise carried on a substrate may be milled to a suitable width for a particular signal type, which may be based in part upon a range of frequencies for which trace or may be used. The thickness and material of the signal substrate 120 may also be selected such that in combination with the optional second ground plane 116 a characteristic impedance may be maintained for signals conveyed by the internal signal trace 110.

A solder or other metal bump (solder bump 202) is applied to the internal signal trace 110. As shown, the solder bump 202 is at or near an end of the signal trace but could be in other locations.

As shown in FIG. 2B, another substrate (intermediate substrate 130) may then optionally be bonded to the signal or bottom substrate 120, via a bonding film 210 (e.g., adhesive) of various types and bonding methods. However, embodiments without such an intermediate layer 130 are within the scope of the present invention and include only the signal substrate 120 and the microstrip substrate 140 (FIG. 1). Also, bonding film layers are shown in FIGS. 2B-E but that is not required as other methods of joining layers are also applicable.

The intermediate substrate 130 includes a hole 204 formed therein to provide access to the terminal end of the signal trace 120 (and the solder bump 202). The hole 142 may be milled before the intermediate substrate 130 is bonded to the signal or bottom substrate 120 or after. However, if after, hole will need to pass through the bonding film 210 so that solder bump can reflow in the hole 204 during bonding.

As shown in FIG. 2C, another substrate microstrip substrate 140 may then be bonded to the intermediate substrate 130, via a bonding film 230 (e.g., adhesive) of various types and bonding methods. Similar to the intermediate substrate 130, the microstrip substrate includes a hole 220 formed therein to provide access the solder bump 202. The hole 220 may be milled before the microstrip substrate 140 is bonded to the intermediate substrate or after. However, if after, hole will need to pass through the bonding film 230. The hole 220 in the microstrip substrate is aligned with hole 204 in the intermediate substrate to allow the conductor 112 to pass through both and contact the solder bump 202. In one embodiment, the microstrip trace 102 is formed on the microstrip substrate 140 before it is bonded to the intermediate substrate 130. For example, microstrip may be a radiator having any of various shapes disposed on the surface of the microstrip substrate 140, such as a linear or spiral signal trace configured to radiate electromagnetic energy, e.g., when fed with an appropriate signal.

In this example, any number of intermediate substrates may be included and some or all of them can include ground planes or traces formed thereon.

After the microstrip substrate 140 is bonded to the intermediate substrate 130, a drill or other implement may be inserted into the holes 204/220 to remove any bonding bond film which may have flowed into them. The drilling process continues downward at least until the solder bump 202 is contacted. The holes 204, 220 may then form a substantially continuous opening through the substrates 140, 150 to provide access to the solder bump 202 and, thus, the internal signal trace 110.

As shown in FIG. 2D, the conductor 112 may be inserted through the holes 204/220 (not shown for clarity) such that it contacts the solder bump 202. In addition to the examples given above, it should also be noted that the conductor 112 is, in one embodiment, a solid coper cylinder having a 5 mil diameter. The conductor 112 substantially fills the holes 204/220 in one embodiment.

A soldering gun or source of heat can be applied to one end of the conductor to cause the solder bump 202 to reflow and form a secure electrical connection between one end of the conductor 112 and internal signal trace 110.

It shall be understood, however, that in one embodiment, the solder ball may not be applied to the internal signal trace 110 as shown above. In such a case, the ball can be place on an end of the conductor 112 that is inserted into the holes 204/220. The conductor can then be heated to reflow the solder ball.

As shown in FIG. 2E, the flat wire connector 150 can be electrically coupled to the microstrip trace 102 and the conductor 112 to electrically couple the two elements together.

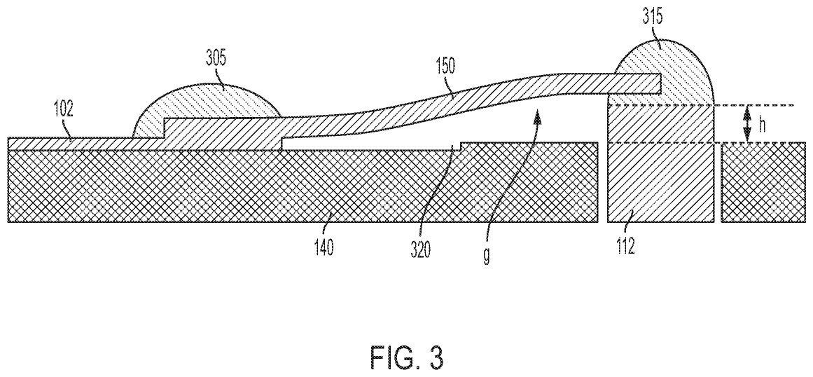

FIG. 3 shows one manner in which the flat wire connector 150 can be electrically coupled to the microstrip trace 102 and the conductor 112. In particular, a first solder bump 305 can be reflowed on a top surface over the flat wire connector 150 to physically bond and electrically couple it to the microstrip trace 102. Similarly, the flat wire connector 150 is physically and electrically coupled to the conductor 112 by reflowing a second solder bump 335 on a top of the conductor 112.

As shown, the conductor extend above the top surface of the microstrip substrate by as indicated by height h. This height is greater than 2 mils in one embodiment. The height h insures that the gap g is formed between the flat wire connector 150 and the upper surface 320 of the microstrip substrate 140.

In the above examples, the conductor 112 connected a microstrip trace to an internal signal trace (e.g., a stripline trace). It shall be understood that the teachings herein could be applied to connect a microstrip ground traces to a ground plane in a co-planar wave guide.

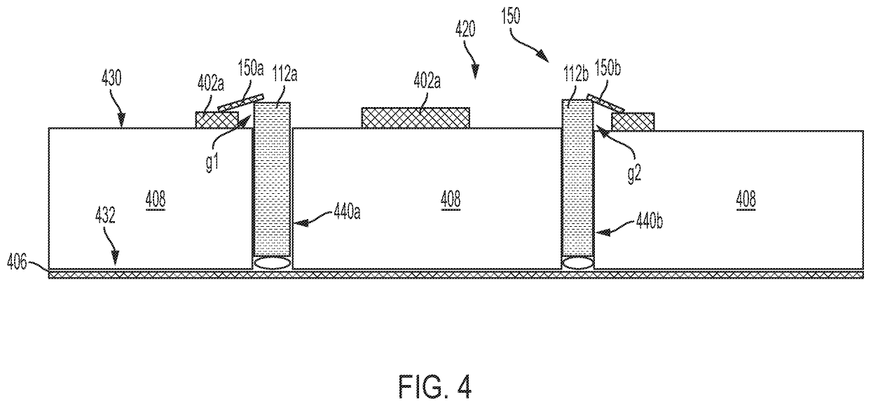

For example, and as shown in FIG. 4, one or more conductor 112a, 112b can connect the first and second (or more) microstrip ground traces 402a, 402b to a ground plane 406 through a substrate 408. A signal microstrip trace 420 is arranged between the microstrip ground traces 402a, 402b.

In more detail, the microstrip ground traces 402a, 402b are on a top surface 430 of the substrate 408 and the ground plane is on a bottom surface 432 of the substrate 408. The substrate 408 includes a first hole 440a passing through the substrate 408 and a second hole 440b that also passes through the substrate 408. A first conductor 112a passes through and substantial filling the first hole 440a and electrically contacts the ground plane 406. The connection between the first conductor 112a and the first conductor can be made by a first solder bump 442a.

Similar to the above, a first flat wire connector 150a electrically connects the first microstrip ground trace 402a to a first end of the first conductor 112a. Thereby, the first conductor 112a electrically connects the first microstrip ground trace 402a to the ground plane 406. The first flat wire connector 150a is arranged such a gap (g1) is formed between the first flat wire 150a and the top surface 430 of the substrate 408.

A second flat wire connector 150b electrically connects the second microstrip ground trace 402b to a first end of the second conductor 112b. Thereby, the second conductor 112a electrically connects the second microstrip ground trace 402b to the ground plane 406. Similar to the above, the second flat wire connector 150b is arranged such a gap (g2) is formed between the second flat wire 150a and the top surface 430 of the substrate 408.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below.

The device can be otherwise oriented (rotated 90 degrees or at other orientations) and the spatially relative descriptors used herein interpreted accordingly.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A circuit structure, comprising:
a signal substrate having a signal trace formed thereon;
a microstrip substrate disposed above the signal substrate that includes a microstrip trace formed thereon and a hole passing through it;
a conductor passing through and substantially filling the hole passing through the microstrip substrate and electrically contacting the signal trace on the signal substrate; and
a flat wire connector electrically connecting the microstrip trace to a first end of the conductor, the flat wire connector being arranged such that a gap is formed between the flat wire connector and a top surface of the microstrip substrate.

2. The circuit board of claim 1, wherein the flat wire connector is soldered to the microstrip trace and a top of the conductor.

3. The circuit structure of claim 1, wherein the conductor is a solid wire.

4. The circuit structure of claim 1, wherein a second end of the conductor is soldered to signal trace.

5. The circuit of claim 1, wherein a top of the conductor extend above the top surface of the microstrip substrate.

6. The circuit structure of claim 1, further including an intermediate substrate located between the signal substrate and the microstrip substrate that includes a hole formed therein and that aligns with the hole passing through the microstrip substrate.

7. The circuit structure of claim 6, wherein the conductor passes thought both the hole passing through the microstrip substrate and the hole formed in the intermediate substrate.

8. A method of manufacturing a circuit structure, the method comprising:
forming a signal trace on a signal substrate;
bonding a microstrip substrate directly or indirectly above the signal substrate;
forming a hole in microstrip substrate;
passing a conductor through the hole to substantially fill the hole passing through the microstrip substrate such that it electrically contacts the signal trace on the signal substrate; and
electrically connecting a flat wire connector to the microstrip and to a first end of the conductor such that a gap is formed between the flat wire connector and a top surface of the microstrip substrate.

9. The method of claim 8, further comprising:
forming a solder ball on the signal trace before passing the conductor through the hole.

10. The method of claim 9, further comprising:
applying heat to the conductor to reflow the solder ball.

11. The method of claim 8, further comprising:
forming a solder ball on a second end of the conductor before passing it through the hole; and
applying heat to the conductor to reflow the solder ball after the conductor is passed through the hole.

12. The method of claim 8, wherein electrically connecting the flat wire connector to the microstrip and to the first end of the conductor includes soldering the flat wire connector to the microstrip and soldering the flat wire connector to the first end of the conductor.

13. The method of 8, wherein the conductor is a solid wire.

14. The method of claim 8, further comprising:
before bonding the microstrip substrate over the signal substrate, bonding an intermediate substrate the signal substrate; and
forming a hole through the intermediate substrate.

15. The method of claim 14, wherein passing a conductor through the hole in the microstrip substrate includes passing the conductor through the hole formed in the intermediate substrate.

16. A coplanar waveguide circuit structure, comprising:
a substrate that includes a first and second microstrip ground traces formed on a top surface thereof, the substrate also including a signal microstrip formed on the top surface and between the first and second microstrip ground traces;
a ground plane dispose on a bottom surface of the substrate;
a first conductor passing through and substantially filling a first hole passing through the substrate and electrically contacting the ground plane; and
a first flat wire connector electrically connecting the first microstrip ground trace to a first end of the first conductor, the first flat wire connector being arranged such that a first gap is formed between the first flat wire connector and the top surface of the substrate.

17. The coplanar waveguide circuit structure of claim 16 further comprising:
a second conductor passing through and substantially filling a second hole passing through the substrate and electrically contacting the ground plane; and
a second flat wire connector electrically connecting the second microstrip ground trace to a first end of the second conductor, the second flat wire connector being arranged such that a second gap is formed between the second flat wire connector and the top surface of the substrate.
